(19) United States
(12) Patent Application Publication
(10) Pub. No.: US 2009/0321707 A1
(43) Pub. Date: Dec. 31, 2009

(54) Intersubstrate-dielectric nanolaminate layer for improved temperature stability of gate dielectric films

(76) Inventors: Matthew Metz, Hillsboro, OR (US); Gilbert Dewey, Hillsboro, OR (US)

Correspondence Address: INTEL CORPORATION;c/o CPA Global, P.O. BOX 52050, MINNEAPOLIS, MN, 55402, US

(21) Appl. No.: 12/215,321

(22) Filed: Jun. 25, 2008

(51) Int. Cl. H01L 47/00; H01L 21/00

(52) U.S. Cl. 257/4; 438/104; 257/E47.005

(57) ABSTRACT

Embodiments of an apparatus with a crystallization-resistant high-κ dielectric and nanolaminate layer stack in a device and methods for forming crystallization-resistant high-κ dielectric and nanolaminate layer stack are generally described herein. Other embodiments may be described and claimed.

### FIELD OF THE INVENTION

The field of invention relates generally to the field of semiconductor integrated circuit manufacturing and, more specifically but not exclusively, relates to microelectronic devices with a low leakage dielectric nanolaminate layer and an adjacent high-κ layer that resists crystallization when exposed to thermal treatment.

### BACKGROUND INFORMATION

Silicon dioxide has been used as a dielectric layer in the manufacture of integrated circuits. As thickness of the dielectric layer scales below 2 nanometers, leakage currents can increase drastically, leading to increased power consumption and reduced device reliability. Replacing silicon dioxide with a high-κ material can provide an integrated circuit manufacturer with an alternative to progressively smaller dielectric layer thicknesses while allowing for increased capacitance of the device. Conventional methods of depositing a high-κ dielectric film on a semiconductor substrate include physical vapor deposition (PVD), metalorganic chemical vapor deposition (MOCVD) and atomic layer deposition (ALD).

### BRIEF DESCRIPTION OF THE DRAWINGS

The present invention is illustrated by way of example and not as a limitation in the figures of the accompanying drawings, in which

FIG. 1 is a flowchart describing one embodiment of a fabrication process used to form an amorphous high-κ layer in a microelectronic device.

FIGS. 2 to 4 illustrate the fabrication of a gate stack for a high-κ/metal gate transistor that includes a polysilicon gate electrode.

FIG. 5 is an illustration of a metal-insulator-metal stack with a nanolaminate layer formed between a conductive layer and a high-κ dielectric layer.

FIG. 6 illustrates a charge storing device situated in a well with a nanolaminate layer formed between a conductive layer and a high-κ dielectric layer.

FIG. 7 is a cross-sectional view of FIG. 6 taken through section line A-A illustrating the charge storing device of FIG. 6.

FIG. 8 is an illustration representing leakage current vs. equivalent oxide thickness of charge storing devices before and after an anneal treatment.

### DETAILED DESCRIPTION

Systems and methods for forming low leakage nanolaminate dielectric stacks are described in various embodiments. In the following description, numerous specific details are set forth such as a description of methods for fabricating a phase-stable amorphous nanolaminate and high-κ dielectric layer stack. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

It would be an advance in the art to control and/or minimize phase transformation of high dielectric constant (high-κ) dielectric layers during the fabrication of a microelectronic device. High-κ dielectric layers may be selectively formed in a fully amorphous state to minimize leakage currents and to maximize capacitance across the one or more layers. High-κ dielectric layers formed with some level of crystallinity, referring to a degree of structural order in the high-κ dielectric layer, may change phase state to a crystalline state when exposed to subsequent processes involving thermal treatments or elevated temperatures. Formation of a nanolaminate and high-κ dielectric layer stack in a fully amorphous phase state can eliminate, minimize, and/or control phase transformation of the one or more high-κ dielectric layers, thereby reducing leakage current in the device. As a result, use of methods to fabricate a phase-stable amorphous nanolaminate and high-κ dielectric layer stack with little to no detectable crystallinity when exposed to subsequent thermal processes can provide improved microelectronic device performance with respect to reduced power consumption and increased device reliability.

In one embodiment, the method comprises providing a substrate for deposition of a phase-stable amorphous nanolaminate and high-κ dielectric layer stack. The nanolaminate layer is formed on the substrate and the nanolaminate layer is exposed to a first gas to form a monolayer. The monolayer is exposed to form an amorphous high-κ layer with little to no crystallinity.

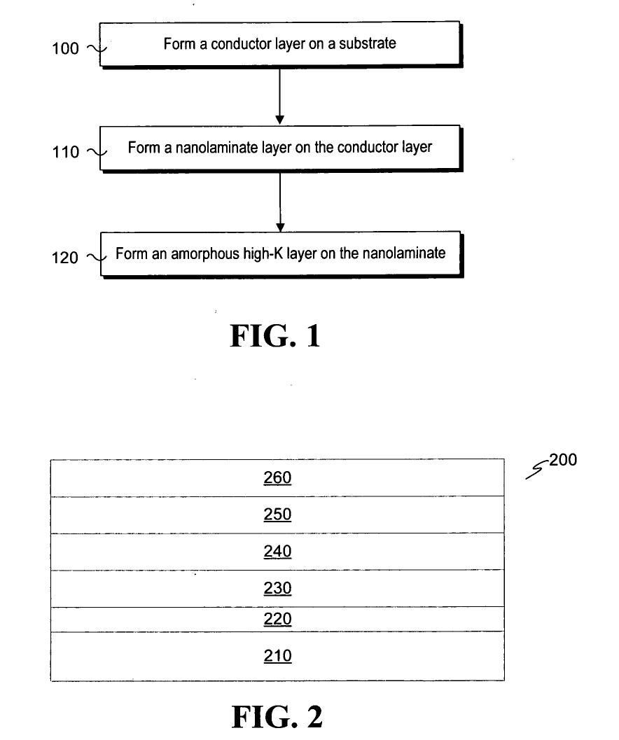

Now turning to the figures, FIG. 1 is a flowchart describing one embodiment of a fabrication process used to form an amorphous nanolaminate and high-κ dielectric layer stack in a microelectronic device. In element 100, a substrate is provided for deposition of a conductor layer. The substrate may comprise a bulk silicon or silicon-on-insulator substructure. Alternatively, the substrate may comprise other materials—which may or may not be combined with silicon—such as: germanium, indium antimonide, lead telluride, indium arsenide, indium phosphide, gallium arsenide, or gallium antimonide. Although a few examples of materials from which the substrate may be formed are described here, any material that may serve as a foundation upon which a semiconductor device may be built falls within the spirit and scope of the present invention.

The conductive layer on the substrate may be formed of a conductive material including one or more transition metals such as titanium (Ti), tantalum (Ta), tungsten (W), copper (Cu), aluminum (Al), titanium nitride (TiN), and tantalum nitride (TaN). Alternately, the conductive layer may be formed of a non-metal conductive material such as doped or undoped polysilicon. In one embodiment, the conductive layer is formed on the substrate using an atomic layer deposition (ALD) process. In other embodiments, the conductive layer is deposited using one or more deposition methods including reactive sputtering, plasma enhanced chemical vapor deposition (PECVD), or physical vapor deposition (PVD).

In another embodiment, an isolation layer is formed between the substrate and the conductive layer, thereby providing a substrate with an isolation/conductive layer stack. Preferably, the isolation layer comprises silicon nitride (Si₃N₄). In an alternate embodiment, the isolation layer comprises one or more dielectric materials known to one skilled in the art to provide isolation between the conductive layer and the substrate. A material type and thickness of the isolation layer is selectively designed to provide electrical isolation between the substrate and the conductive layer.

In element 110, a nanolaminate layer is formed on the conductor layer. The nanolaminate layer may be a thin dielectric layer comprising yttrium (such as yttrium oxide, Y₂O₃) formed using ALD in a reactor chamber. The nanolaminate layer may also comprise aluminum oxide (Al₂O₃), scandium oxide (Sc₂O₃), a lanthanide oxide (Ln2O3, e.g. La2O3, Dy2O3, Gd2O3, etc.) and bimetallic oxide combinations such as LaAlO3 or GdDyO3. ALD is a pulsed form of chemical vapor deposition (CVD) in a sequence of self-limiting gas-solid reactions on a substrate surface with a deposition temperature that is dependent on the selection of precursors. In one embodiment, the deposition temperature ranges between 250 to 350 degrees Celsius (°C.). In this embodiment, the deposition temperature is a control temperature of the wafer and/or substrate during formation of the nanolaminate layer. The degree of vacuum is controlled in the range of about 0.01-10 torr and preferably between 1 to 5 torr depending on an atomic layer deposition chamber design and related gas flows. In an embodiment where tri-methyl aluminum (Al(CH₃)₃) is used as a precursor, the deposition temperature may be as low as 15° C. In another embodiment where a halide based precursor is used, the deposition temperature may be as high as 500° C. A thickness of the nanolaminate layer is selected to provide an amorphous initiation layer for subsequent layer deposition.

Surface saturating adsorption results in self-limiting growth during ALD. As a result, ALD can achieve excellent film thickness control over complex substrate topography. In one embodiment, the nanolaminate layer is an amorphous thin layer of yttria (Y₂O₃) formed from a tris(cyclopentadienyl)yttrium (Ycp) vapor precursor and a water vapor precursor in alternating gas pulses. The reactor chamber may be purged between each precursor gas pulse to remove unadsorbed precursor from the reactor chamber.

In element 120, the amorphous nanolaminate layer is exposed to a first high-κ precursor to form a monolayer on the surface of the amorphous nanolaminate layer. The amorphous nanolaminate layer serves as an initiation layer for a layer formed upon it, thereby establishing a template effect for an adjacent amorphous layer. In one embodiment for the formation of a zirconium oxide layer, the first precursor may comprise zirconium tetrachloride (ZrCl₄) or a zirconium amide source. In another embodiment for the formation of a hafnium oxide layer, the first high-κ precursor may comprise hafnium tetrachloride or a hafnium amide source. In a further embodiment in the formation of an aluminum oxide layer, the first high-κ precursor may be aluminum chloride (AlCl₃) or tri-methyl aluminum (Al(CH₃)₃). The monolayer is exposed to a second high-κ precursor to form an amorphous or substantially amorphous high-κ layer such as zirconium oxide, hafnium oxide, or aluminum oxide. The second precursor may be one or more of water vapor (H2O), oxygen (O2), nitrous oxide (N2O), ozone (O3), one or more alcohols such as isopropyl alcohol and t-butanol, and silanols.

The processes of forming a monolayer with a first precursor, optionally purging any unadsorbed first precursor, and exposing the monolayer to a second precursor can be repeatedly performed until a fully amorphous. high-κ layer is obtained. The process of forming the fully amorphous high-κ layer is performed at a deposition temperature substantially between 250 to 350° C. for zirconium oxide. In this embodiment, the deposition temperature is a control temperature of the wafer and/or substrate during formation of the high-κ layer. Deposition temperature is selected for each set of precursor reactants to deposit a film that is amorphous or substantially amorphous as deposited. The degree of vacuum is controlled in the range of about 0.01-10 torr and preferably between 1-5 torr depending on an atomic layer deposition chamber design and related precursor flows.

In an alternate embodiment, elements 110 and 120 are repeated to form a multi-laminate stack of alternating nanolaminate and high-κ gate dielectric layers on the conductor layer formed in element 100. This embodiment may be selected for applications where an effectively thicker amorphous nanolaminate and high-κ gate dielectric stack is desired. In this embodiment, amorphous nanolaminate layers are selectively inserted to limit a thickness of a continuous high-κ gate dielectric layer and limiting an ability of the high-κ gate dielectric layer to change phase from an amorphous phase to a polycrystalline or crystalline phase when exposed to subsequent processes, such as thermal processes.

FIGS. 2 to 4 illustrate the fabrication of a transistor gate stack that includes an amorphous nanolaminate layer between the substrate and gate dielectric. Starting with FIG. 2, an amorphous nanolaminate and high-κ dielectric layer stack 200 includes a substrate 210, upon which an amorphous nanolaminate layer 220, high-κ gate dielectric layer 230, a metal layer 240, an optional barrier metal layer 250, and a gate electrode layer 260 are formed.

The n 220 may be a thin dielectric layer comprising yttrium, such as yttrium oxide (Y₂O₃) formed using an ALD process in a reactor chamber. A thickness of the amorphous nanolaminate layer 220 may be approximately equal to 2 angstroms (Å) and may range approximately between 2 to 5 Å.

The high-κ gate dielectric layer 230 is preferably formed on the substrate using an ALD process. Alternately, the high-κ gate dielectric layer 230 is deposited using a conventional deposition method, e.g., a conventional chemical vapor deposition (“CVD”), low pressure CVD, or physical vapor deposition (“PVD”) process. In an embodiment where the amorphous nanolaminate layer 220 and the high-κ gate dielectric layer 230 are formed in a gate stack, a high-κ gate dielectric layer 230 thickness should be less than about 60 Å, and more preferably between about 5 Å and about 40 Å in thickness.

Some of the materials that may be used to make the high-κ gate dielectric layer 230 include: hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Particularly preferred are hafnium oxide, zirconium oxide, and aluminum oxide. Although a few examples of materials that may be used to form the high-κ gate dielectric layer 230 are described here, that layer may be made from other materials.

The metal layer 240 may be formed using any conductive material from which a metal gate electrode may be derived, and may be formed on high-κ gate dielectric layer 230 using well known physical vapor deposition (PVD), CVD, or ALD processes. When the metal layer 240 will serve as an N-type workfunction metal, metal layer 240 preferably has a workfunction that is between about 3.9 eV and about 4.2 eV. N-type materials that may be used to form the metal layer 240 include hafnium, zirconium, titanium, tantalum, aluminum, and metal carbides that include these elements, i.e., titanium carbide, zirconium carbide, tantalum carbide, hafnium carbide and aluminum carbide. When the metal layer 240 will serve as a P-type workfunction metal, metal layer 240 preferably has a workfunction that is between about 4.9 eV and about 5.2 eV. P-type materials that may be used to form the metal layer 240 include ruthenium, palladium, platinum, cobalt, nickel, and conductive metal oxides, e.g., ruthenium oxide. The metal layer 240 should be thick enough to ensure that any material formed on it will not significantly impact its workfunction. Preferably, the metal layer 240 is between about 10 Å and about 300 Å thick, and more preferably is between about 10 Å and about 200 Å thick. Although a few examples of materials that may be used to form the metal layer 240 are described here, that layer may be made from many other materials.

The barrier metal layer 250, if used, may be formed using materials that include, but are not limited to, titanium nitride and tantalum nitride. The barrier metal layer 250 serves to protect the metal layer 240 and the high-κ gate dielectric layer 230. The gate electrode layer 260 serves as a conductive fill material for a high-κ/metal gate stack. The gate electrode layer 260 may be formed from materials such as polysilicon or a metal such as aluminum. In some implementations, polysilicon is used as a sacrificial gate electrode that is later replaced with a metal gate electrode. In some implementations, a sacrificial material may be used as are well known in the art.

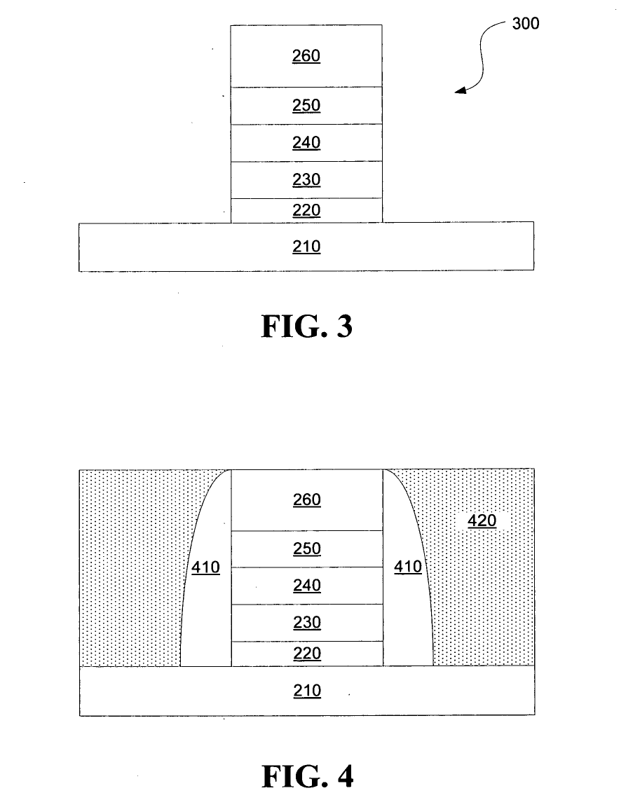

As shown in FIG. 3, the layers deposited on the substrate 200 are then patterned to form a gate stack 300. Patterning processes are well known in the art. For instance, one patterning process begins by depositing a photoresist material (not shown) over the gate electrode layer 260 and patterning the photoresist using ultraviolet radiation and an optical mask to define features such as the gate stack 300 in the resist layer. The photoresist layer (not shown) is developed to form a photoresist mask that protects the defined features, such as the portion of the underlying layers that will form the gate stack 300. An etchant is then applied to remove unprotected portions of the underlying layers, yielding a patterned gate stack 300.

Turning to FIG. 4, a pair of spacers 410 and an inter-layer dielectric (ILD) layer 420 are formed on the substrate 210. The spacers 410 are formed adjacent to the gate stack 300 by depositing a material, such as silicon nitride (Si₃N₄), on the substrate 210 and then etching the material to form the pair of spacers 410. After the spacers 410 are formed, a dielectric material is deposited and polished to form the ILD layer 420. Dielectric materials that may be used for the ILD layer 420 include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layer 420 may include pores or other voids to further reduce its dielectric constant. A source region and a drain region (not shown) may have been formed in the substrate 210 prior to deposition of the ILD layer 420.

In another embodiment, a metal-nanolaminate-insulator-metal stack 500 is formed, at least in part, using the method described in FIG. 1 and illustrated in FIG. 5 wherein a metal-nanolaminate-insulator-metal stack 500 with the amorphous nanolaminate layer 220 is formed between a first conductive layer 510 and a amorphous high-κ dielectric layer 520. A second conductive layer 530 is formed on, the amorphous high-κ dielectric layer 520. In an alternate embodiment, the amorphous nanolaminate layer 220 and the amorphous high-κ dielectric layer 520 are repeated to form a multi-laminate stack of alternating nanolaminate and high-κ gate dielectric layers on the first conductive layer 510 (not shown). The metal-nanolaminate-insulator-metal stack 500 may be formed on a flat substrate, or any two dimensional or three dimensional surface such as the surface of a recess or well, as illustrated in the following embodiment.

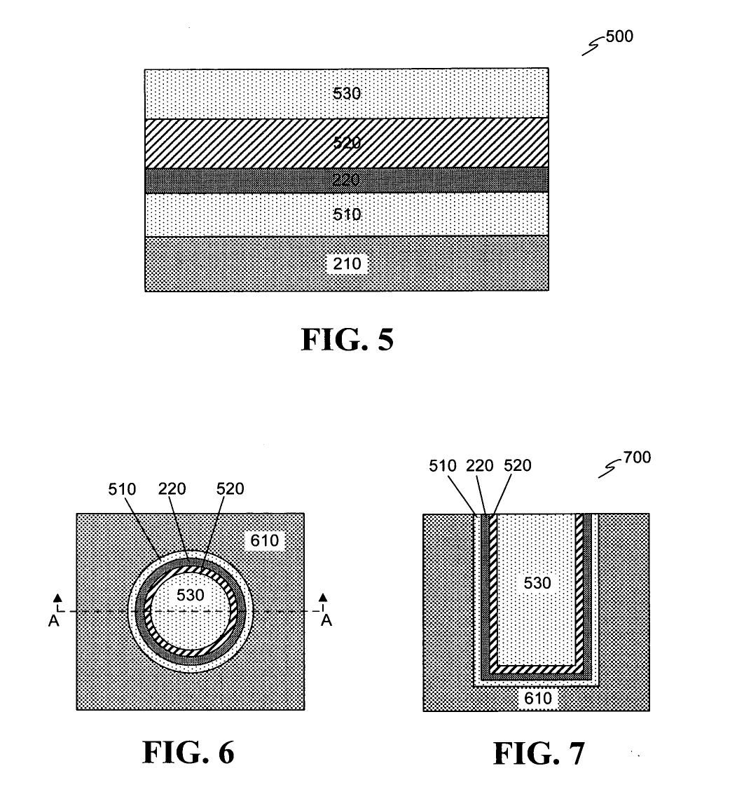

FIG. 6 illustrates an embodiment of a charge storing device situated in a well formed in an isolation region 610 with a amorphous nanolaminate layer 220 formed between the first conductive layer 510 and the amorphous high-κ dielectric layer 520 to create a charge storing device, such as a metal-insulator-metal (MIM) capacitor structure 700 illustrated in FIG. 7. The second conductive layer 530 may be formed using an ALD process, a physical vapor deposition process (PVD), or another deposition process known to one skilled in the art. The second conductive layer 530 illustrated in FIG. 6 and FIG. 7 completely fills the remainder of the original recess. In another embodiment, the second conductive layer 530 fills only a portion of the remaining recess by forming a sidewall with a nominal thickness along the exposed surface of the amorphous high-κ dielectric layer 520. A thickness of the second conductive layer 530 is selectively designed to provide a signal path. For example, a thickness of the second conductive layer 530 is greater than approximately 10 angstroms. In some applications, the thickness of the second conductive layer 530 is established by a diameter of a remaining recess, as illustrated in FIG. 7.

MIM capacitors 700 may be used for a number of functions, for example, as a reservoir capacitor for a charge pump circuit or for noise decoupling. MIM capacitors 700 are valuable components in logic, memory and analog circuits and are typically configured to provide a minimal footprint, thereby minimizing a surface area of an integrated circuit (IC) when viewed from the top of the IC.

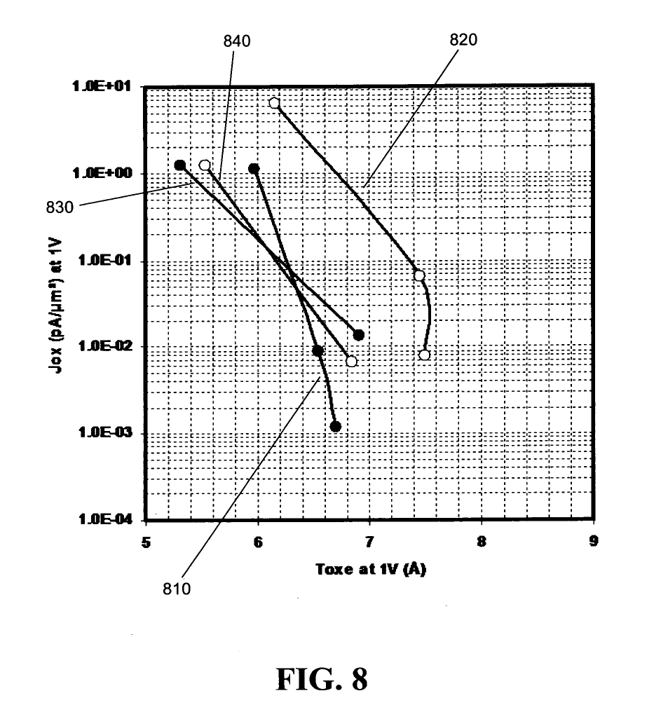

FIG. 8 is an illustration representing leakage current (Jox) vs. equivalent oxide thickness (Toxe) of MIM devices before and after a forming gas anneal treatment. Line 810 with closed circles represent characteristics of MIM devices prepared using prior art practices prior to performing an anneal treatment step. Line 820 with open circles represent characteristics of MIM devices prepared using prior art practices after performing a forming gas anneal treatment. Line 830 with the closed circles represents characteristics of a MIM device comprising a metal-nanolaminate-insulator-metal stack 500 and phase-stable amorphous high-κ dielectric layer prepared using methods and structures described herein. Line 840 with the open circles represents characteristics of a MIM device comprising a metal-nanolaminate-insulator-metal stack 500 and phase-stable amorphous high-κ dielectric layer prepared using methods and structures described herein after forming gas anneal treatment. As shown in FIG. 8, the MIM device comprising a metal-nanolaminate-insulator-metal stack 500 and phase-stable amorphous high-κ dielectric layer prepared using the methods described herein unexpectantly provides substantially thinner equivalent oxide thickness (resulting in a higher capacitance) along with lower leakage. By way of example, it is shown that MIM devices comprising a metal-nanolaminate-insulator-metal stack 500 and phase-stable amorphous high-κ dielectric layer prepared using the methods described herein may result in about two orders of magnitude less leakage than MIM devices prepared using prior art practices.

A plurality of embodiments of an apparatus and methods for forming an amorphous nanolaminate and amorphous high-κ dielectric layer stack in a device have been described. The foregoing description of the embodiments of the invention has been presented for the purposes of illustration and description. It is not intended to be exhaustive or to limit the invention to the precise forms disclosed. This description and the claims following include terms, such as left, right, top, bottom, over, under, upper, lower, first, second, etc. that are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer. The embodiments of a device or article described herein can be manufactured, used, or shipped in a number of positions and orientations.

However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

Various operations will be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming an integrated circuit, comprising:
forming a conductor layer on a substrate;
exposing the conductor layer to a first precursor to form a monolayer on the conductor layer;
exposing the monolayer to a second precursor to form an amorphous nanolaminate layer;
forming an amorphous high-κ dielectric layer on the amorphous nanolaminate layer to provide a phase-stable amorphous nanolaminate and high-κ dielectric layer stack.

2. The method of claim 1, further including forming a second conductive layer on the amorphous high-κ dielectric layer.

3. The method of claim 1, wherein a thickness of the amorphous nanolaminate layer ranges approximately between 2 to 5 Å.

4. The method of claim 1, wherein the amorphous high-κ dielectric layer is selected from the group consisting of ZrO2, HfO2, and Al2O3.

5. The method of claim 1, wherein the amorphous nanolaminate layer is selected from the group consisting of aluminum oxide (Al₂O₃), scandium oxide (Sc₂O₃), a lanthanide oxide, and a bimetallic oxide.

6. The method of claim 1, wherein the amorphous high-κ dielectric layer is fully amorphous.

7. The method of claim 1, further including an isolation layer between the substrate and the conductive layer.

8. An integrated circuit, comprising:
a conductor layer on a substrate;
a nanolaminate layer on the conductor layer;
a high-κ dielectric layer on the nanolaminate layer formed at a phase state; and
a spacer directly adjacent to the high-κ dielectric layer, wherein the phase state of the high-κ dielectric layer is substantially unchanged after forming the spacer.

9. The integrated circuit of claim 8, further including a second conductive layer on the high-κ dielectric layer.

10. The integrated circuit of claim 8, wherein a thickness of the nanolaminate layer ranges approximately between 2 to 5 Å.

11. The integrated circuit of claim 8, wherein the high-κ dielectric layer is selected from the group consisting of ZrO2, HfO2, and Al2O3.

12. The integrated circuit of claim 8, wherein the nanolaminate layer is selected from the group consisting of aluminum oxide (Al₂O₃), scandium oxide (Sc₂O₃), a lanthanide oxide, and a bimetallic oxide.

13. The integrated circuit of claim 8, wherein the high-κ dielectric layer is fully amorphous.

14. The integrated circuit of claim 8, further including an isolation layer between the substrate and the conductive layer.

15. A device configured for charge storage, comprising:
a first conductor on an exposed surface of a well;
a nanolaminate layer on the first conductor;
a phase-stable amorphous high-κ dielectric layer directly adjacent to the nanolaminate layer; and
a second conductor on the high-κ amorphous dielectric layer.

16. The device of claim 15, wherein a thickness of the nanolaminate layer ranges approximately between 2 to 5 Å.

17. The device of claim 15, wherein the phase-stable amorphous high-κ dielectric layer is selected from the group consisting of ZrO2, HfO2, and Al2O3.

18. The device of claim 15, wherein the nanolaminate layer is selected from the group consisting of aluminum oxide (Al₂O₃), scandium oxide (Sc₂O₃), a lanthanide oxide, and a bimetallic oxide.

19. The device of claim 15, wherein the phase-stable amorphous high-κ dielectric layer is fully amorphous.

20. The device of claim 15, further including an isolation layer between the substrate and the conductive layer.
